(19) United States
(12) Patent Application Publication
(10) Pub. No.: US 2026/0118390 A1
(43) Pub. Date: Apr. 30, 2026

(54) BIDIRECTIONAL CURRENT SENSING DEVICE, CURRENT SENSING SYSTEM INCLUDING THE SAME, AND METHOD OF OPERATING THE CURRENT SENSING SYSTEM

(71) Applicant: SAMSUNG ELECTRONICS CO., LTD., Suwon-si (KR)

(72) Inventor: Youngwoo CHUNG, Suwon-si (KR)

(73) Assignee: SAMSUNG ELECTRONICS CO., LTD., Suwon-si (KR)

(21) Appl. No.: 19/294,865

(22) Filed: Aug. 8, 2025

(30) Foreign Application Priority Data
Oct. 24, 2024 (KR) 10-2024-0146920
Jan. 23, 2025 (KR) 10-2025-0010099

(51) Int. Cl. G01R 19/00

(52) U.S. Cl. CPC G01R 19/0092

(57) ABSTRACT

A current sensing device measures a target current flowing through a target transistor connected between a first voltage terminal and a second voltage terminal The current sensing device includes a sensing transistor circuit including first to fourth transistor circuits and an operational amplifier connected to the sensing transistor circuit, and when the target current flows in a first direction from the first voltage terminal to the second voltage terminal, the first and fourth transistor circuits are turned on based on a first gate voltage, the second and third transistor circuits are turned off based on a second gate voltage, and when the target current flows in a second direction opposite to the first direction, the first and fourth transistor circuits are turned off based on the second gate voltage, and the second and third transistor circuits are turned on based on the first gate voltage.

### CROSS-REFERENCE TO RELATED APPLICATIONS

This application claims priority under 35 U.S.C. § 119 to Korean Patent Application No. 10-2024-0146920 filed on Oct. 24, 2024, and Korean Patent Application No. 10-2025-0010099 filed on Jan. 23, 2025, in the Korean Intellectual Property Office, the disclosures of which are incorporated by reference herein in their entireties.

### BACKGROUND

The present disclosure relates to a current sensing device, and more particularly, to a bidirectional current sensing device, a current sensing system including the same, and a method of operating the current sensing system.

As the demand for high-performance and long-life semiconductor devices increases, it is necessary to accurately sense the current flowing in transistors so as to detect the abnormal current flowing in the transistors of the semiconductor devices or to quickly control the abnormal current.

In the current sensors, a current having a certain ratio with respect to the current flowing through a sensing target transistor flows in a sensing transistor. In this case, the sensing ratio is determined by the ratio of the sensing target transistor and the sensing transistor, but when the current flowing through the sensing target transistor is measured in both directions, there is a problem that the sensing ratio is not uniform depending on the input voltage and temperature applied to the sensing target transistor due to the switching transistor that determines a path of a sensing current.

### SUMMARY

Embodiments of the present disclosure provide a bidirectional current sensing device, a current sensing system including the same, and a method of operating the current sensing system.

According to an aspect of the disclosure, a current sensing device for measuring a target current flowing through a target transistor connected between a first voltage terminal and a second voltage terminal, the current sensing device including: a sensing transistor circuit including a first transistor circuit, a second transistor circuit, a third transistor circuit, and a fourth transistor circuit; and an operational amplifier connected to the sensing transistor circuit, wherein the first transistor circuit is connected between the first voltage terminal and a first input terminal of the operational amplifier, wherein the second transistor circuit is connected between the first voltage terminal and a second input terminal of the operational amplifier, wherein the third transistor circuit is connected between the second voltage terminal and the first input terminal of the operational amplifier, wherein the fourth transistor circuit is connected between the second voltage terminal and the second input terminal of the operational amplifier, wherein, based on the target current flowing in a first direction from the first voltage terminal to the second voltage terminal, the first transistor circuit and the fourth transistor circuit are turned on based on a first gate voltage, and the second transistor circuit and the third transistor circuit are turned off based on a second gate voltage, and wherein, based on the target current flowing in a second direction opposite to the first direction, the first transistor circuit and the fourth transistor circuit are turned off based on the second gate voltage, and the second transistor circuit and the third transistor circuit are turned on based on the first gate voltage.

According to an aspect of the disclosure, there is provided a current sensing system for measuring a target current flowing through a target transistor connected between a first voltage terminal and a second voltage terminal, the current sensing system including: a current sensing device including a sensing transistor circuit and an operational amplifier connected to the sensing transistor circuit, the sensing transistor circuit including a first transistor circuit, a second transistor circuit, a third transistor circuit and a fourth transistor circuit; and a controller configured to control the current sensing device, and wherein the first transistor circuit is connected between the first voltage terminal and a first input terminal of the operational amplifier, wherein the second transistor circuit is connected between the first voltage terminal and a second input terminal of the operational amplifier, wherein the third transistor circuit is connected between the second voltage terminal and the first input terminal of the operational amplifier, wherein the fourth transistor circuit is connected between the second voltage terminal and the second input terminal of the operational amplifier, and wherein the controller is further configured to: based on the target current flowing in a first direction from the first voltage terminal to the second voltage terminal, based on a first mode signal, apply a first gate voltage to the first transistor circuit and the fourth transistor circuit to turn on the first transistor circuit and the fourth transistor circuit, and apply a second gate voltage to the second transistor circuit and the third transistor circuit to turn off the second transistor circuit and the third transistor circuit, and based on the target current flowing in a second direction opposite to the first direction, based on a second mode signal, apply the second gate voltage to the first transistor circuit and the fourth transistor circuit to turn off the first transistor circuit and the fourth transistor circuit, and apply the first gate voltage to the second transistor circuit and the third transistor circuit to turn on the second transistor circuit and the third transistor circuit.

According to an aspect of the disclosure, there is provided a method of operating a current sensing system for measuring a target current flowing through a target transistor connected between a first voltage terminal and a second voltage terminal, wherein the current sensing system includes a current sensing device, a controller controlling the current sensing device, and a processor providing a first mode signal or a second mode signal to the controller, the method including: determining, by the processor, whether the target current flows in a first direction from the first voltage terminal to the second voltage terminal; providing, by the processor, the first mode signal to the controller based on determining that the target current flows in the first direction; and providing, by the controller, a first gate voltage to a first transistor circuit and a fourth transistor circuit of the current sensing device and a second gate voltage to a second transistor circuit and a third transistor circuit of the current sensing device, based on the first mode signal, wherein the first transistor circuit is connected between the first voltage terminal and a first input terminal of an operational amplifier of the current sensing device, wherein the second transistor circuit is connected between the first voltage terminal and a second input terminal of the operational amplifier, wherein the third transistor circuit is connected between the second voltage terminal and the first input terminal of the operational amplifier, and wherein the fourth transistor circuit is connected between the second voltage terminal and the second input terminal of the operational amplifier.

### BRIEF DESCRIPTION OF THE DRAWINGS

The above and other objects and features of the present disclosure will become apparent by describing in detail embodiments thereof with reference to the accompanying drawings, in which:

FIG. 1 is a circuit diagram illustrating a current sensing device, according to one or more embodiments of the present disclosure;

FIG. 2 is a circuit diagram embodying a first transistor circuit of FIG. 1;

FIG. 3 is a circuit diagram illustrating a current sensing device when a target current flows in a first direction, according to one or more embodiments of the present disclosure;

FIG. 4 is a circuit diagram illustrating a current sensing device when a target current flows in a second direction, according to one or more embodiments of the present disclosure;

FIG. 5 is a circuit diagram illustrating a current sensing device when a target current does not flow, according to one or more embodiments of the present disclosure;

FIG. 6 is a block diagram illustrating a current sensing system, according to one or more embodiments of the present disclosure;

FIG. 7 is a circuit diagram embodying a controller of FIG. 6;

FIG. 8 is a circuit diagram illustrating a controller when a target current flows in a first direction, according to one or more embodiments of the present disclosure;

FIG. 9 is a circuit diagram illustrating a controller when a target current flows in a second direction, according to one or more embodiments of the present disclosure;

FIG. 10 is a circuit diagram illustrating a controller when a target current does not flow, according to one or more embodiments of the present disclosure; and

FIG. 11 is a flowchart illustrating a method of operating a current sensing system of FIG. 6.

### DETAILED DESCRIPTION

Hereinafter, certain example embodiments of the present disclosure will be described in detail such that those skilled in the art may easily carry out the present disclosure.

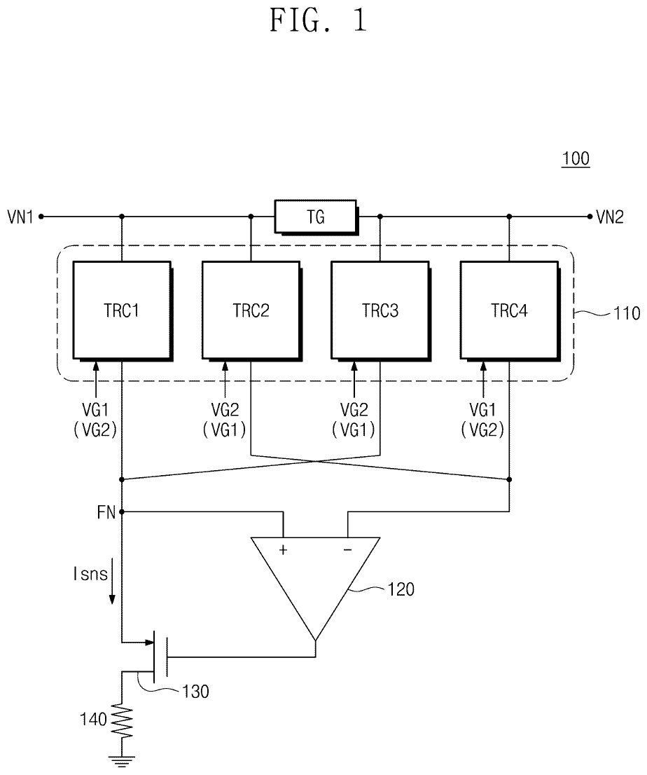

FIG. 1 is a circuit diagram illustrating a current sensing device 100, according to one or more embodiments of the present disclosure. Referring to FIG. 1, a circuit diagram of the current sensing device 100 is illustrated.

The current sensing device 100 may sense a target current flowing through the target transistor. The current sensing device 100 may measure the magnitude of the target current flowing through a target transistor TG in a first direction. Alternatively, the current sensing device 100 may measure the magnitude of the target current flowing through the target transistor TG in the opposite direction to the first direction.

For example, the current sensing device 100 may provide an electrical signal corresponding to the magnitude of the measured target current to a control component located inside or outside the current sensing device 100. The electrical signal corresponding to the magnitude of the target current may be an analog signal or a digital signal.

In detail, the control component may perform a current sensing operation or a current regulating operation based on the electrical signal corresponding to the magnitude of the target current. The control component may compare the electrical signal with a threshold value. The control component may sense a target current greater than a first threshold value or a target current less than a second threshold value less than the first threshold value. The control component may control the current sensing device 100 to allow a target current within a predetermined range to flow to the target transistor TG.

The current sensing device 100 may include the target transistor TG, a sensing transistor circuit 110, an operational amplifier 120, a PMOS transistor 130, and a sensing resistor 140.

The target transistor TG has a gate to which a first gate voltage VG1 is applied, and may be connected between a first voltage terminal VN1 and a second voltage terminal VN2. The first voltage terminal VN1 may have a first voltage level, and the second voltage terminal VN2 may have a second voltage level.

Based on a difference between the first voltage level and the second voltage level, the target current may flow in a first direction or a second direction. The first direction may refer to a direction in which current flows from the first voltage terminal VN1 to the second voltage terminal VN2. The second direction may indicate a direction in which current flows from the second voltage terminal VN2 to the first voltage terminal VN1.

In one or more embodiments, the target transistor TG may be an NMOS (N-type Metal Oxide Semiconductor) transistor. A source of the target transistor TG may be connected to the first voltage terminal VN1, and a drain of the target transistor TG may be connected to the second voltage terminal VN2. However, embodiments of the present disclosure are not limited thereto, and the target transistor TG may be a PMOS (P-type Metal-Oxide-Semiconductor) transistor. Furthermore, the current sensing device 100 may sense current flowing in an electrical element in which current may flow in both directions as the target current.

In one or more embodiments, a diode may be connected between the source and the drain of the target transistor TG. The diode may prevent reverse current.

The sensing transistor circuit 110 may include first to fourth transistor circuits TRC1 to TRC4.

Each of the first to fourth transistor circuits TRC1 to TRC4 may be turned on or off depending on an applied gate voltage. A current flows between the two terminals of the transistor circuit that is turned on among the first to fourth transistor circuits TRC1 to TRC4. A current does not flow between the two terminals of the transistor circuit that is turned off among the first to fourth transistor circuits TRC1 to TRC4.

The first transistor circuit TRC1 may be connected between the first voltage terminal VN1 and a first input terminal (e.g., a non-inverting terminal) of the operational amplifier 120. When the first transistor circuit TRC1 is turned on, a current may flow between the first voltage terminal VN1 and the first input terminal. In contrast, when the first transistor circuit TRC1 is turned off, a current may not flow between the first voltage terminal VN1 and the first input terminal.

The second transistor circuit TRC2 may be connected between the first voltage terminal VN1 and a second input terminal (e.g., an inverting terminal) of the operational amplifier 120. When the second transistor circuit TRC2 is turned on, a current may flow between the first voltage terminal VN1 and the second input terminal. In contrast, when the second transistor circuit TRC2 is turned off, a current may not flow between the first voltage terminal VN1 and the second input terminal.

The third transistor circuit TRC3 may be connected between the second voltage terminal VN2 and the first input terminal of the operational amplifier 120. When the third transistor circuit TRC3 is turned on, a current may flow between the second voltage terminal VN2 and the first input terminal. In contrast, when the third transistor circuit TRC3 is turned off, a current may not flow between the second voltage terminal VN2 and the first input terminal.

The fourth transistor circuit TRC4 may be connected between the second voltage terminal VN2 and the second input terminal of the operational amplifier 120. When the fourth transistor circuit TRC4 is turned on, a current may flow between the second voltage terminal VN2 and the second input terminal. In contrast, when the fourth transistor circuit TRC4 is turned off, a current may not flow between the second voltage terminal VN2 and the second input terminal.

In one or more embodiments, each of the first to fourth transistor circuits TRC1 to TRC4 may be turned on based on the application of a first gate voltage, or may be turned off based on the application of a second gate voltage.

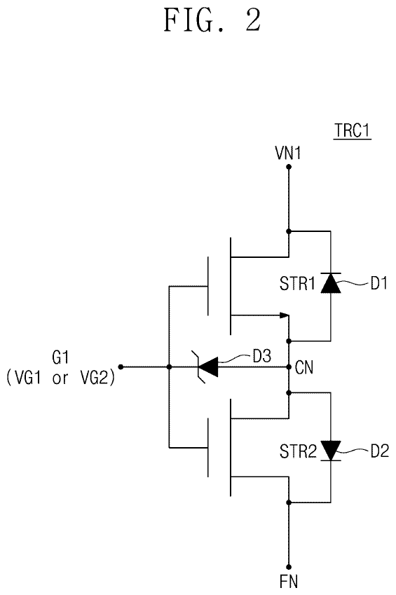

In one or more embodiments, each of the first to fourth transistor circuits TRC1 to TRC4 may include at least one sensing transistor. For example, the first transistor circuit TRC1 may include one sensing transistor connected between the first voltage terminal VN1 and the first input terminal. As another example, the first transistor circuit TRC1 may include two or more sensing transistors, and the two or more sensing transistors may be connected in series between the first voltage terminal VN1 and the first input terminal. In this case, applying a gate voltage to each of the first to fourth transistor circuits TRC1 to TRC4 means applying the corresponding gate voltage to the gates of all sensing transistors included in each. A more detailed description of this will be described later with reference to FIG. 2. However, embodiments of the present disclosure are not limited thereto, and will include examples of various circuit designs that may be represented by one equivalent transistor connected between the two terminals of the first transistor circuit TRC1. Each of the second to fourth transistor circuits TRC2 to TRC4 is similar to the first transistor circuit TRC1.

In one or more embodiments, each of the first to fourth transistor circuits TRC1 to TRC4 may be turned on when the first gate voltage VG1 is applied, and may be turned off when a second gate voltage VG2 is applied. For example, a voltage level of the first gate voltage is higher than a voltage level of the second gate voltage, and a voltage level of the second gate voltage is higher than a voltage level of a ground voltage.

The first transistor circuit TRC1 and the fourth transistor circuit TRC4 may be applied with the same gate voltage. In addition, the second transistor circuit TRC2 and the third transistor circuit TRC3 may be applied with the same gate voltage and different from the gate voltage applied to the first transistor circuit TRC1.

Which gate voltage is applied to each of the first to fourth transistor circuits TRC1 to TRC4 is determined based on the direction of the target current.

When the target current flows in the first direction, the first transistor circuit TRC1 and the fourth transistor circuit TRC4 may be applied with the first gate voltage VG1, and the second transistor circuit TRC2 and the third transistor circuit TRC3 may be applied with the second gate voltage VG2.

When the target current flows in the second direction, the first transistor circuit TRC1 and the fourth transistor circuit TRC4 may be applied with the second gate voltage VG2, and the second transistor circuit TRC2 and the third transistor circuit TRC3 may be applied with the first gate voltage VG1.

The operational amplifier 120 amplifies the difference between a voltage applied to the first input terminal and a voltage applied to the second input terminal. The operational amplifier 120 may output an output voltage through an output terminal. The first input terminal may be connected to a feedback terminal FN and may receive a feedback voltage.

The PMOS transistor 130 may have a gate connected to the output terminal of the operational amplifier 120 to receive the output voltage, and may be connected between the first input terminal (or, the feedback terminal FN) and the sensing resistor 140. For example, a source of the PMOS transistor 130 may be connected to the first input terminal (or, the feedback terminal FN), and a drain of the PMOS transistor 130 may be connected to the sensing resistor 140.

In addition, a voltage of the feedback terminal FN, i.e., the feedback voltage, may have a voltage level that is almost the same as the voltage applied to the second input terminal.

The sensing resistor 140 may be connected between the drain of the PMOS transistor 130 and a ground voltage terminal.

The current sensing device 100 may measure the target current based on a sensing voltage signal across the sensing resistor 140. In detail, the current sensing device 100 may obtain the sensing voltage signal across the sensing resistor 140. The current sensing device 100 may obtain a magnitude of a sensing current Isns based on the size of the sensing resistor 140 and the voltage magnitude of the sensing voltage signal. The sensing current Isns may refer to a current flowing from the feedback terminal FN through the PMOS transistor 130 to the sensing resistor 140. A ratio of the magnitude of the target current and the magnitude of the sensing current Isns may be the same as a sensing ratio of the current sensing device 100. The sensing ratio of the current sensing device 100 may be determined by a ratio of the target resistance and the sensing resistance. The target resistance may refer to an equivalent resistance corresponding to the target transistor TG between the first voltage terminal VN1 and the second voltage terminal VN2. The sensing resistance may refer to an equivalent resistance corresponding to a turned-on transistor circuit TRC between the first voltage terminal VN1 (or, the second voltage terminal VN2) and the feedback terminal FN.

In one or more embodiments, the equivalent resistance corresponding to the turned-on transistor is the same as the resistance connected between the source and the drain of the corresponding transistor. In detail, the equivalent resistance may be determined by the following equation:

$$R = \frac{1}{k p \frac{W}{L} ( {V}_{g s} - {V}_{t o} )} .$$

In this case, R refers to the equivalent resistance, kp refers to the product of the mobility of holes and the gate oxide capacitance per unit area as a constant, W refers to a width of a channel, L refers to a length of the channel, Vgs refers to the gate-source voltage, and Vto refers to the threshold voltage.

FIG. 2 is a circuit diagram embodying the first transistor circuit TRC1 of FIG. 1, according to one or more embodiments of the present disclosure. Referring to FIG. 2, a circuit diagram of the first transistor circuit TRC1 is illustrated. Each of the second to fourth transistor circuits TRC2 to TRC4 of FIG. 1 may be configured similarly to the first transistor circuit TRC1 of FIG. 2.

As described above, the first transistor circuit TRC1 may be one sensing transistor connected between the first voltage terminal VN1 and the feedback terminal FN, or may be represented as one sensing transistor (i.e., may be considered as one equivalent transistor). Hereinafter, an embodiment in which the first transistor circuit TRC1 includes two sensing transistors STR1 and STR2 connected in series between the first voltage terminal VN1 and the feedback terminal FN will be described. Through this, damage to the inside of the first transistor circuit TRC1 may be prevented and stable operation may be achieved.

The first sensing transistor STR1 may be connected to a first gate terminal G1 and may be connected between the first voltage terminal VN1 and a connection terminal CN. The second sensing transistor STR2 may be connected to the first gate terminal G1 and may be connected between the connection terminal CN and the feedback terminal FN. Each of the first sensing transistor STR1 and the second sensing transistor STR2 may be applied with the same gate voltage (e.g., the first gate voltage VG1 or the second gate voltage VG2) through the first gate terminal G1.

In one or more embodiments, each of the two sensing transistors STR1 and STR2 may be a transistor of the same type as the target transistor TG of FIG. 1. For example, both the target transistor and the two sensing transistors STR1 and STR2 may be NMOS transistors.

In one or more embodiments, a first diode D1 may be connected between the source and drain of the first sensing transistor STR1. For example, the first diode D1 may be a body diode of the first sensing transistor STR1. A second diode D2 may be connected between the source and drain of the second sensing transistor STR2. For example, the second diode D2 may be a body diode of the second sensing transistor STR2. The body diode is not an actual diode, but may refer to a structure that is formed during a manufacturing process and performs a function similar to a diode.

In one or more embodiments, a third diode D3 may be connected between the connection terminal CN and the first gate terminal G1. The third diode D3 may be a zener diode. The difference between the voltage level of the connection terminal CN and the voltage level applied to the first gate terminal G1 may be maintained below a preset threshold voltage level by the third diode D3.

However, the circuit structure of the first transistor circuit TRC1 is not limited to FIG. 2, and it will be obvious that at least one of the first to third diodes D1, D2, and D3 for the stability of the first transistor circuit TRC1 may be omitted or replaced with a set of other electrical elements performing a similar function.

As the first gate voltage VG1 is applied to the first gate terminal G1 and the first and second sensing transistors STR1 and STR2 are turned on, a current (e.g., a sensing current) may flow between the first voltage terminal VN1 and the feedback terminal FN.

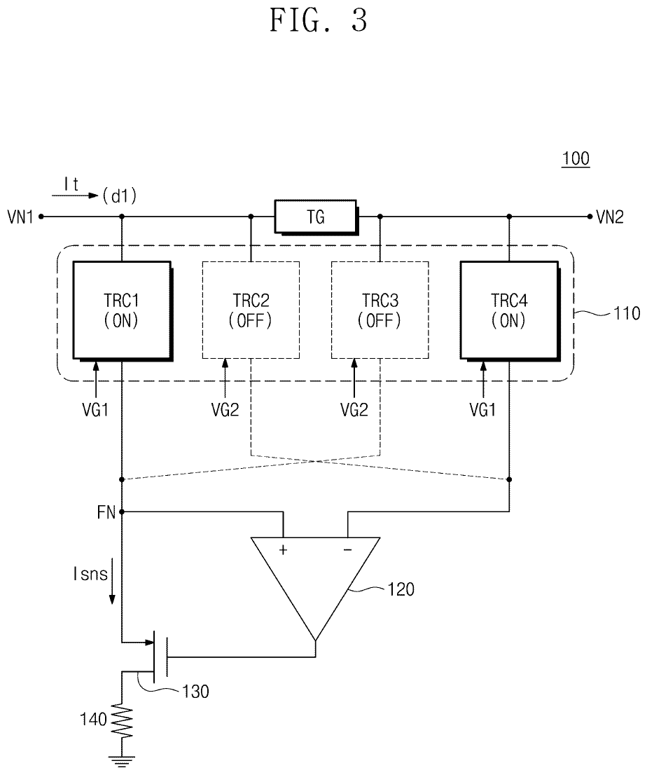

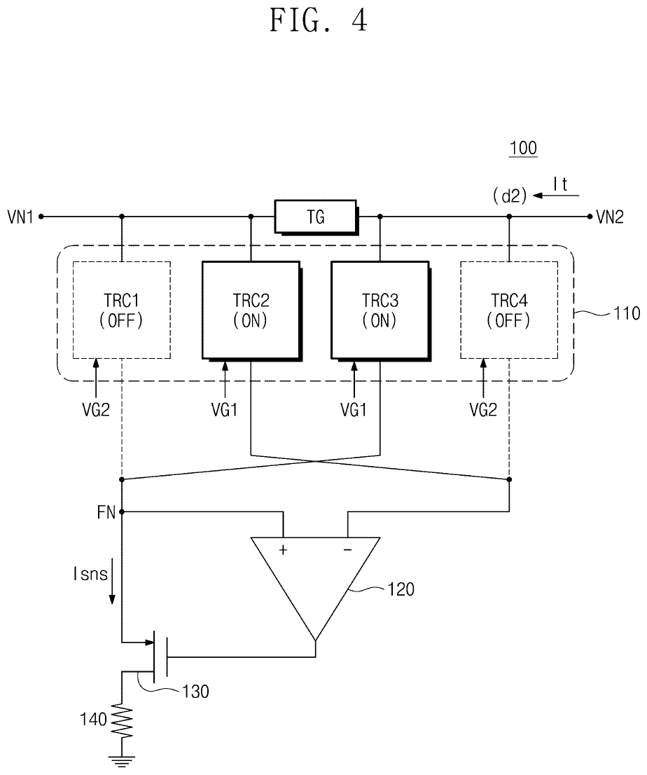

Hereinafter, the operations of the current sensing device 100 of FIG. 1 according to the direction of the target current will be described with reference to FIGS. 3 and 4, respectively.

FIG. 3 is a circuit diagram illustrating a current sensing device when a target current flows in a first direction, according to one or more embodiments of the present disclosure. Referring to FIG. 3, the operation of the current sensing device 100 when a target current “It” flows in a first direction d1 is described. The sensing transistor circuit 110, the operational amplifier 120, the PMOS transistor 130, and the sensing resistor 140 of FIG. 3 may correspond to the sensing transistor circuit 110, the operational amplifier 120, the PMOS transistor 130, and the sensing resistor 140 of FIG. 1, respectively.

The first transistor circuit TRC1 and the fourth transistor circuit TRC4 are turned on by applying the first gate voltage VG1. The second transistor circuit TRC2 and the third transistor circuit TRC3 are turned off by applying the second gate voltage VG2. In this case, the turned-off configuration or the signal line through which no current flows is depicted as a dashed line in FIG. 3.

The sensing current Isns may flow through the feedback terminal FN to the sensing resistor 140 via the first transistor circuit TRC1. In this case, a predetermined pull-down current may flow through the fourth transistor circuit TRC4. The pull-down current may be based on a pull-down resistor connected between the fourth transistor circuit TRC4 and the ground voltage terminal. Through this, stable operation of the turned-on fourth transistor circuit TRC4 may be ensured.

The current sensing device 100 may measure the target current “It” based on the sensing current Isns flowing through the first transistor circuit TRC1. In detail, the current sensing device 100 may measure the sensing current Isns based on the sensing voltage signal across the sensing resistor 140. The current sensing device 100 may determine the magnitude of the target current depending on a sensing ratio based on the ratio of the equivalent resistance of the target transistor TG and the equivalent resistance of the first transistor circuit TRC1.

FIG. 4 is a circuit diagram illustrating a current sensing device when a target current flows in a second direction, according to one or more embodiments of the present disclosure. Referring to FIG. 4, the operation of the current sensing device 100 when the target current “It” flows in a second direction d2 is described. The sensing transistor circuit 110, the operational amplifier 120, the PMOS transistor 130, and the sensing resistor 140 of FIG. 4 may correspond to the sensing transistor circuit 110, the operational amplifier 120, the PMOS transistor 130, and the sensing resistor 140 of FIG. 1, respectively.

The first transistor circuit TRC1 and the fourth transistor circuit TRC4 are turned off by applying the second gate voltage VG2. The second transistor circuit TRC2 and the third transistor circuit TRC3 are turned on by applying the first gate voltage VG1. In this case, the turned-off configuration or the signal line through which no current flows is depicted as a dashed line in FIG. 4.

The sensing current Isns may flow through the feedback terminal FN to the sensing resistor 140 via the third transistor circuit TRC3. In this case, a predetermined pull-down current may flow through the second transistor circuit TRC2. The pull-down current may be based on a pull-down resistor connected between the second transistor circuit TRC2 and the ground voltage terminal. Through this, stable operation of the turned-on second transistor circuit TRC2 may be ensured.

The current sensing device 100 may measure the target current “It” based on the sensing current Isns flowing through the third transistor circuit TRC3. In detail, the current sensing device 100 may measure the sensing current Isns based on the sensing voltage signal across the sensing resistor 140. The current sensing device 100 may determine the magnitude of the target current depending on a sensing ratio based on the ratio of the equivalent resistance of the target transistor TG and the equivalent resistance of the third transistor circuit TRC3.

The current sensing device 100 according to the present disclosure may determine the path through which the sensing current Isns flows by turning on or off each of the first to fourth transistor circuits TRC1 to TRC4 depending on the direction of the target current “It”. In detail, since a separate transistor that switches according to the direction of the target current “It” is not required in the path through which the sensing current Isns flows, the current sensing device 100 according to the present disclosure may maintain a sensing ratio that is less affected by the temperature and the magnitude of an input voltage.

For example, when there is a transistor for switching in addition to the sensing transistor in the path through which the sensing current Isns flows, there is a problem that the sensing ratio may vary since the transistor for switching itself may be treated as a part of the sensing transistor (i.e., the equivalent resistance may increase). In addition, when the transistor for switching is a different type of transistor from the target transistor, there is a problem that the sensing ratio may vary due to a difference in electrical characteristics caused by the difference in type. In addition, when the voltage applied to the first voltage terminal VN1 or the second voltage terminal VN2 varies, there is a problem that the gate-source voltage may vary and the sensing ratio may vary.

When the target current “It” flows in the first direction, the sensing current Isns of the current sensing device 100 according to the present disclosure may flow along the first transistor circuit TRC1. Since there is no transistor for switching, the sensing ratio may be uniform depending on the ratio of the equivalent resistances of the target transistor TG and the first transistor circuit TRC1. In addition, since the magnitude of the gate-source voltage of the target transistor TG is the same as the magnitude of the gate-source voltage of the first transistor circuit TRC1, the sensing ratio may be uniform according to the ratio of the equivalent resistances.

In contrast, the sensing ratio may be maintained uniformly similar to the above description even when the target current “It” flows in the second direction.

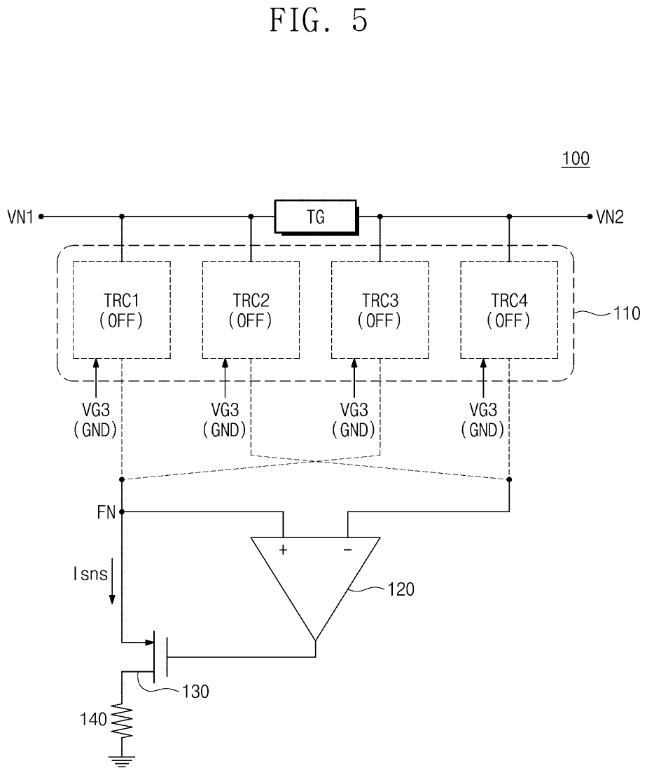

FIG. 5 is a circuit diagram illustrating a current sensing device when a target current does not flow, according to one or more embodiments of the present disclosure. Referring to FIG. 5, the operation of the current sensing device 100 when the current does not flow through the target transistor TG is described. Alternatively, the operation when the current sensing device 100 does not operate is described. The sensing transistor circuit 110, the operational amplifier 120, the PMOS transistor 130, and the sensing resistor 140 of FIG. 5 may correspond to the sensing transistor circuit 110, the operational amplifier 120, the PMOS transistor 130, and the sensing resistor 140 of FIG. 1, respectively.

Each of the first to fourth transistor circuits TRC1 to TRC4 may be turned off by receiving a third gate voltage VG3. The third gate voltage VG3 may be the same as a ground voltage GND. In this case, the sensing current for measuring the target current may not flow in the current sensing device 100.

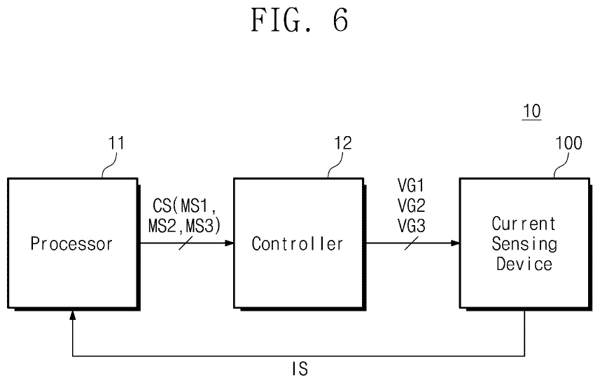

FIG. 6 is a block diagram illustrating a current sensing system, according to one or more embodiments of the present disclosure. Referring to FIG. 6, a current sensing system 10 including a processor 11, a controller 12, and the current sensing device 100 is illustrated. The current sensing device 100 may correspond to the current sensing device 100 of FIG. 1.

The current sensing system 10 may control the current sensing device 100 to measure a current flowing through a target transistor. The current sensing system 10 may perform a current sensing operation based on the measured target current. The current sensing system 10 may sense an abnormal current based on the current sensing operation and may notify a user of the abnormal state (e.g., display the abnormal state on a display). Alternatively, when an abnormal current is sensed, the current sensing system 10 may control at least one of a voltage applied to the gate of the target transistor, a voltage applied to the first voltage terminal, and a voltage applied to the second voltage terminal such that a current within a predetermined allowable range flows through the target transistor. However, embodiments of the present disclosure are not limited thereto, and the current sensing system 10 may convert the magnitude of the measured target current into a digital value so as to store, to display on a display, or to use for calculation.

The processor 11 may determine whether the direction of the current flowing through the target transistor is the first direction or the second direction. The processor 11 may provide control signals CS to the controller 12 based on the determination.

For example, when the direction of the current flowing in the target transistor is determined to be the first direction, the processor 11 may provide the control signals CS that allow the controller 12 to apply the first gate voltage VG1 to the first and fourth transistor circuits of the current sensing device 100 and to apply the second gate voltage VG2 to the second and third transistor circuits. In this case, the set of these control signals CS may be referred to as a first mode signal MS1.

As another example, when the direction of the current flowing in the target transistor is determined to be the second direction, the processor 11 may provide the control signals CS that allow the controller 12 to apply the first gate voltage VG1 to the second and third transistor circuits of the current sensing device 100 and to apply the second gate voltage VG2 to the first and fourth transistor circuits. In this case, the set of these control signals CS may be referred to as a second mode signal MS2.

Furthermore, the processor 11 may determine that a current does not flow through the target transistor of the current sensing device 100 or to stop the sensing operation of the current sensing device 100. In this case, the processor 11 may provide the control signals CS that allow the controller 12 to provide the ground voltage as the third gate voltage VG3 to each of the first to fourth transistor circuits of the current sensing device 100. In this case, the set of these control signals CS may be referred to as a third mode signal MS3.

In one or more embodiments, the processor 11 may be implemented by hardware, software, firmware, or any combination thereof. For example, the processor 11 may be a CPU (Central Processing Unit), an AP (Application Processor), a GPU (Graphics Processing Unit), an NPU (Neural Processing Unit), or a DSP (Digital Signal Processor). For example, the target transistor sensed by the current sensing device 100 may be a power transistor of a mobile device, and in this case, the processor 11 may be an AP.

The processor 11 may receive a sensing current signal IS from the current sensing device 100. The sensing current signal IS may be an analog signal or a digital signal corresponding to the magnitude of the target current. For example, the processor 11 may convert the sensing current signal IS, which is an analog signal, into a digital value. The processor 11 may perform a current sensing operation or a current regulation operation based on the sensing current signal IS. However, embodiments of the present disclosure are not limited thereto, and as described with reference to FIG. 1, the current sensing operation or the current regulation operation may be performed inside the current sensing device 100.

The controller 12 may control the current sensing device 100 based on the control signals CS received from the processor 11. The controller 12 may provide a gate voltage to each of the first to fourth transistor circuits of the current sensing device 100. For example, the controller 12 may provide the first gate voltage VG1, the second gate voltage VG2, and the third gate voltage VG3 to the current sensing device 100.

For example, the controller 12 may control the current sensing device 100 based on the first mode signal MS1 such that the sensing current flows to the first transistor circuit. In this case, the current sensing device 100 may operate as described with reference to FIG. 3. The controller 12 may control the current sensing device 100 based on the second mode signal MS2 such that the sensing current flows to the third transistor circuit. In this case, the current sensing device 100 may operate as described with reference to FIG. 4. The controller 12 may control the current sensing device 100 based on the third mode signal MS3 such that the sensing current does not flow. In this case, the current sensing device 100 may operate as described with reference to FIG. 5.

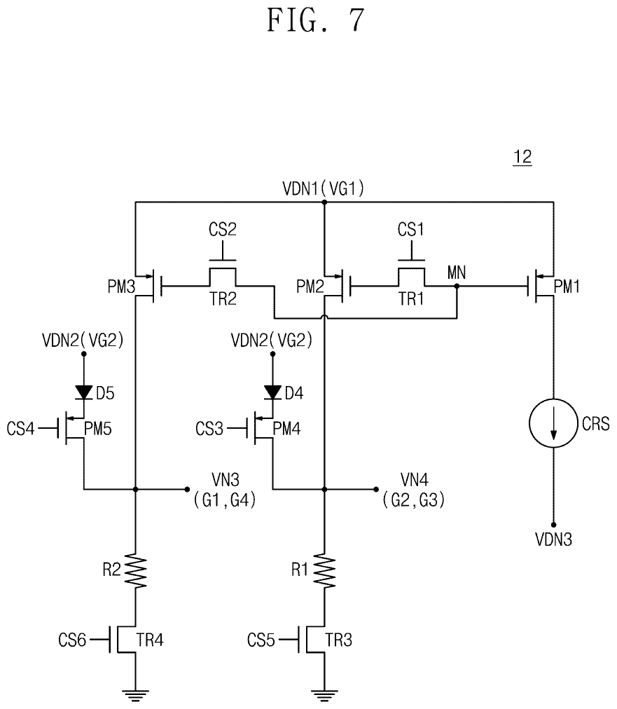

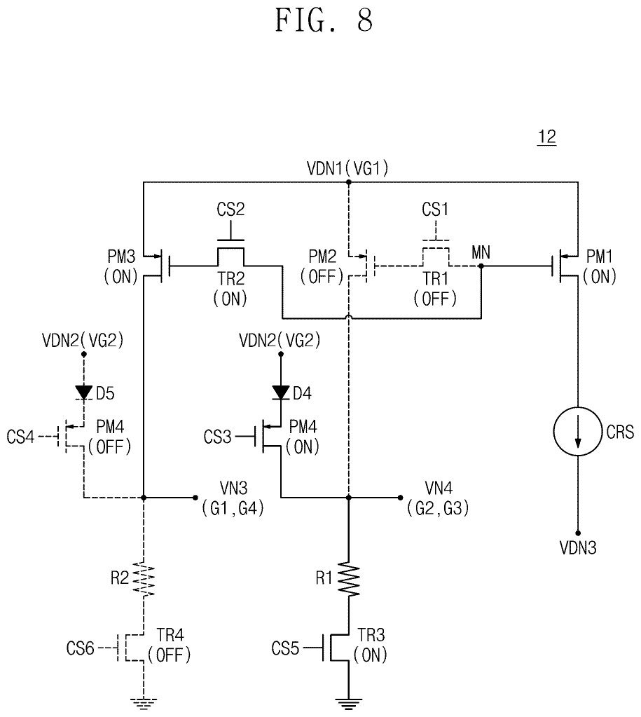

Hereinafter, a circuit diagram of the controller 12 implemented as a circuit at least in part according to one or more embodiments of the present disclosure is described with reference to FIG. 7, and the operation of the controller 12 according to each of the mode signals MS1 to MS3 is described with reference to FIGS. 8 to 10. Regarding FIG. 6, the controller 12 outputs gate control voltages. FIGS. 7-10 illustrate the current sensing device 100 of FIG. 6 receiving the gate voltages from the controller 12. FIGS. 7-10 illustrate the effect of the controller 12 on the current sensing device 100.

FIG. 7 is a circuit diagram embodying the controller 12 of FIG. 6. Referring to FIG. 7, a circuit diagram of the controller 12 is illustrated.

The controller 12 may include a third voltage terminal VN3 connected to the first gate terminal G1 of the first transistor circuit of the current sensing device and a fourth gate terminal G4 of the fourth transistor circuit. In detail, the voltage level of the third voltage terminal VN3 may be provided to the first gate terminal G1 and the fourth gate terminal G4 using pads or pins, etc. In addition, the controller 12 may include a fourth voltage terminal VN4 connected to a second gate terminal G2 of the second transistor circuit of the current sensing device and a third gate terminal G3 of the third transistor circuit. In detail, the voltage level of the fourth voltage terminal VN4 may be provided to the second gate terminal G2 and the third gate terminal G3 using pads or pins, etc.

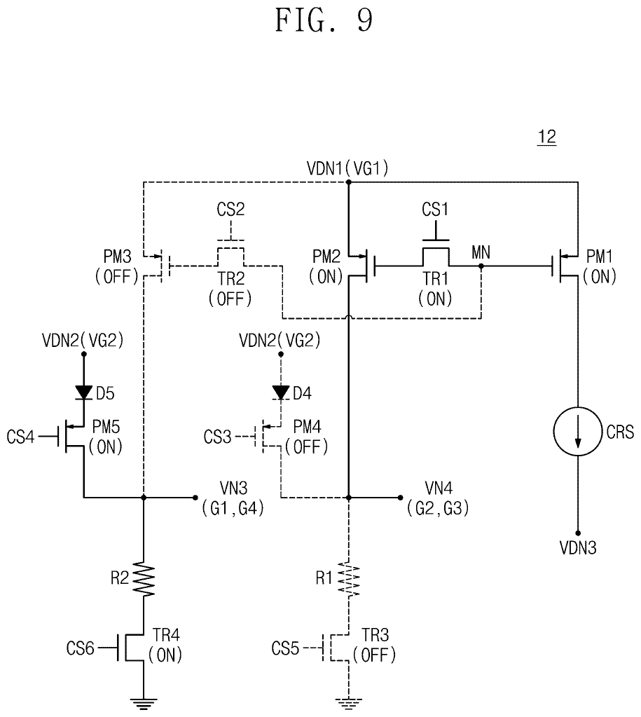

For example, the controller 12 may form a current mirror between the third voltage terminal VN3 and a first power supply voltage terminal VDN1 to which the first gate voltage VG1 is applied, thereby raising the voltage level of the third voltage terminal VN3 to the voltage level of the first gate voltage VG1. A more detailed description of this will be described later with reference to FIG. 8. The controller 12 may form a path between a second power supply voltage terminal VDN2 to which the second gate voltage VG2 is applied passing through the third voltage terminal VN3 and the ground voltage terminal, thereby raising the voltage of the third voltage terminal VN3 to the voltage level of the second gate voltage VG2. A more detailed description of this will be described later with reference to FIG. 9. The voltage level of the fourth voltage terminal VN4 is also raised to the voltage level of the first gate voltage VG1 or the voltage level of the second gate voltage VG2 in a similar manner to the case of the third voltage terminal VN3, and a more detailed description thereof will be described later with reference to FIGS. 8 and 9.

The controller 12 may include a current source CRS, first to fifth PMOS transistors PM1 to PM5, first to fourth transistors TR1 to TR4, a first resistor R1, and a second resistor R2.

The first PMOS transistor PM1 has a gate connected to a mirror terminal MN and may be connected between the first power supply voltage terminal VDN1 and the current source CRS.

The current source CRS may be connected between a drain of the first PMOS transistor PM1 and a third power supply voltage terminal VDN3.

The first transistor TR1 has a gate that receives a first control signal CS1 and may be connected between the mirror terminal MN and a gate of the second PMOS transistor PM2.

The second PMOS transistor PM2 has a gate connected to the first transistor TR1 and may be connected between the first power supply voltage terminal VDN1 and the fourth voltage terminal VN4.

The second transistor TR2 has a gate that receives a second control signal CS2 and may be connected between the mirror terminal MN and a gate of the third PMOS transistor PM3.

The third PMOS transistor PM3 has a gate connected to the second transistor TR2 and may be connected between the first power supply voltage terminal VDN1 and the third voltage terminal VN3.

The fourth PMOS transistor PM4 has a gate that receives a third control signal CS3 and may be connected between the second power supply voltage terminal VDN2 and the fourth voltage terminal VN4.

In one or more embodiments, a fourth diode D4 may be connected between the fourth PMOS transistor PM4 and the second power supply voltage terminal VDN2. The current direction from the second power supply voltage terminal VDN2 to the fourth PMOS transistor PM4 may be maintained by the fourth diode D4.

The fifth PMOS transistor PM5 has a gate that receives a fourth control signal CS4 and may be connected between the second power supply voltage terminal VDN2 and the third voltage terminal VN3.

In one or more embodiments, a fifth diode D5 may be connected between the fifth PMOS transistor PM5 and the second power supply voltage terminal VDN2. The current direction from the second power supply voltage terminal VDN2 to the fifth PMOS transistor PM5 may be maintained by the fifth diode D5.

The first resistor R1 may be connected between the fourth voltage terminal VN4 and a terminal other than a gate of the third transistor TR3. The third transistor TR3 has a gate that receives a fifth control signal CS5 and may be connected between the first resistor R1 and the ground voltage terminal.

The second resistor R2 may be connected between the third voltage terminal VN3 and a terminal other than a gate of the fourth transistor TR4. The fourth transistor TR4 has a gate that receives a sixth control signal CS6 and may be connected between the second resistor R2 and the ground voltage terminal.

FIG. 8 is a circuit diagram illustrating the controller 12 when a target current flows in a first direction, according to one or more embodiments of the present disclosure. Referring to FIG. 8, the controller 12 is described in which the first gate voltage VG1 is applied to the third voltage terminal VN3 and the second gate voltage VG2 is applied to the fourth voltage terminal VN4, based on the first mode signal. Each component of FIG. 8 may correspond to the component having the same reference symbol in FIG. 7.

Based on the first mode signal received from the processor, the second transistor TR2 may be turned on by the second control signal CS2, the fifth PMOS transistor PM5 may be turned off by the fourth control signal CS4, and the fourth transistor TR4 may be turned off by the sixth control signal CS6.

For example, the first PMOS transistor PM1 and the third PMOS transistor PM3 may form a current mirror having gates connected to each other through the mirror terminal MN. A mirror current having a uniform ratio with respect to the reference current flowing in the current source CRS may flow through the third PMOS transistor PM3. In this case, the uniform ratio may be determined by the ratio of the size of the first PMOS transistor PM1 and the size of the third PMOS transistor PM3. In this case, the voltage level of the fourth voltage terminal VN4 may be the same as the voltage level of the first gate voltage VG1. Accordingly, the first gate voltage VG1 may be applied to the first gate terminal G1 and the fourth gate terminal G4.

In addition, based on the first mode signal received from the processor, the first transistor TR1 may be turned off by the first control signal CS1, the fourth PMOS transistor PM4 may be turned on by the third control signal CS3, and the third transistor TR3 may be turned on by the fifth control signal CS5.

For example, as a path is formed from the second power supply voltage terminal VDN2 to the ground voltage terminal through the fourth voltage terminal VN4, the voltage level of the fourth voltage terminal VN4 may be the same as the voltage level of the second gate voltage VG2. Accordingly, the second gate voltage VG2 may be applied to the second gate terminal G2 and the third gate terminal G3.

FIG. 9 is a circuit diagram illustrating the controller 12 when a target current flows in a second direction, according to one or more embodiments of the present disclosure. Referring to FIG. 9, the controller 12 is described in which the second gate voltage VG2 is applied to the third voltage terminal VN3 and the first gate voltage VG1 is applied to the fourth voltage terminal VN4, based on the second mode signal. Each component of FIG. 9 may correspond to the component having the same reference symbol in FIG. 7.

Based on the second mode signal received from the processor, the second transistor TR2 may be turned off by the second control signal CS2, the fifth PMOS transistor PM5 may be turned on by the fourth control signal CS4, and the fourth transistor TR4 may be turned on by the sixth control signal CS6.

For example, as a path is formed from the second power supply voltage terminal VDN2 to the ground voltage terminal through the third voltage terminal VN3, the voltage level of the third voltage terminal VN3 may be the same as the voltage level of the second gate voltage VG2. Accordingly, the second gate voltage VG2 may be applied to the first gate terminal G1 and the fourth gate terminal G4.

In addition, based on the second mode signal received from the processor, the first transistor TR1 may be turned on by the first control signal CS1, the fourth PMOS transistor PM4 may be turned off by the third control signal CS3, and the third transistor TR3 may be turned off by the fifth control signal CS5.

For example, the first PMOS transistor PM1 and the second PMOS transistor PM2 may form a current mirror having gates connected to each other through the mirror terminal MN. A mirror current may have a uniform ratio with respect to the reference current flowing in the current source CRS may flow through the second PMOS transistor PM2. In this case, the uniform ratio may be determined by the ratio of the size of the first PMOS transistor PM1 and the size of the second PMOS transistor PM2. In this case, the voltage level of the fourth voltage terminal VN4 may be the same as the voltage level of the first gate voltage VG1. Accordingly, the first gate voltage VG1 may be applied to the second gate terminal G2 and the third gate terminal G3.

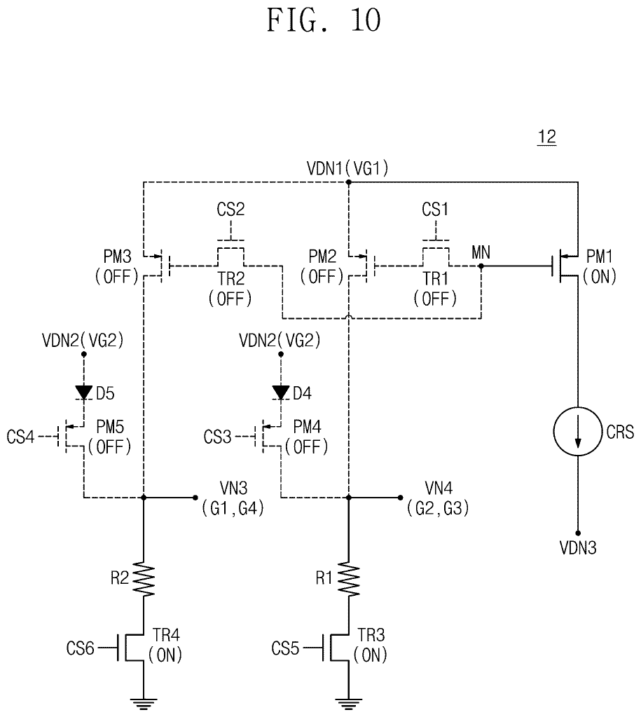

FIG. 10 is a circuit diagram illustrating the controller 12 when a target current does not flow, according to one or more embodiments of the present disclosure. Referring to FIG. 10, the operation of the controller 12 that allows the current sensing device 100 to stop operation is described.

Based on the third mode signal received from the processor, the second transistor TR2 may be turned off by the second control signal CS2, the fifth PMOS transistor PM5 may be turned off by the fourth control signal CS4, and the fourth transistor TR4 may be turned on by the sixth control signal CS6.

For example, since a path is formed between the third voltage terminal VN3 and the ground voltage terminal and a current does not flow, the voltage level of the third voltage terminal VN3 may be the same as the voltage level of the ground voltage. Therefore, the ground voltage may be applied to the first gate terminal G1 and the fourth gate terminal G4.

In addition, based on the third mode signal received from the processor, the first transistor TR1 may be turned off by the first control signal CS1, the fourth PMOS transistor PM4 may be turned off by the third control signal CS3, and the third transistor TR3 may be turned on by the fifth control signal CS5.

For example, since a path is formed between the fourth voltage terminal VN4 and the ground voltage terminal and a current does not flow, the voltage level of the fourth voltage terminal VN4 may be the same as the voltage level of the ground voltage. Therefore, the ground voltage may be applied to the second gate terminal G2 and the third gate terminal G3.

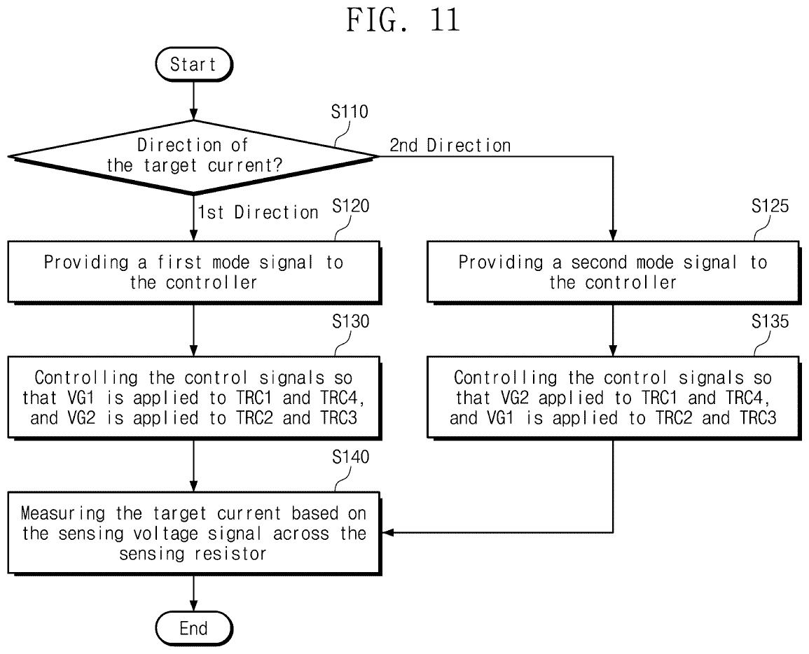

FIG. 11 is a flowchart illustrating a method of operating the current sensing system 10 of FIG. 6. Referring to FIG. 11, an operation method of the current sensing system 10 is described.

In operation S110, the current sensing system 10 may determine whether the direction of the target current flowing through the target transistor is the first direction or the second direction. When the direction of the target current is the first direction, operation S120 may be performed, and in contrast, when the direction of the target current is the second direction, operation S125 may be performed.

In operation S120, the current sensing system 10 may provide a first mode signal to the controller in response to determining that the direction of the target current is the first direction.

In operation S130, the current sensing system 10 may provide the first gate voltage VG1 to each of the first transistor circuit and the fourth transistor circuit of the current sensing device, and may provide the second gate voltage VG2 to each of the second transistor circuit and the third transistor circuit, based on the control signals of the first mode signal, using the controller.

In this case, the first to fourth transistor circuits may correspond to the first to fourth transistor circuits TRC1 to TRC4 of FIG. 1, respectively.

In operation S125, the current sensing system 10 may provide a second mode signal to the controller in response to determining that the direction of the target current is the second direction.

In one or more embodiments, operations S110, S120, and S125 may be performed by the processor of the current sensing system 10. However, embodiments of the present disclosure are not limited thereto, and may be performed by a logic block within the current sensing system 10 rather than the processor.

In operation S135, the current sensing system 10 may provide the first gate voltage VG1 to each of the second transistor circuit and the third transistor circuit of the current sensing device, and may provide the second gate voltage VG2 to each of the first transistor circuit and the fourth transistor circuit, based on the control signals of the second mode signal, using the controller.

In operation S140, the current sensing system 10 may measure the target current based on the sensing voltage signal across the sensing resistor of the current sensing device, using the current sensing device.

In one or more embodiments, the first input terminal of the operational amplifier of the current sensing device is connected to the feedback terminal to receive the feedback voltage, and the current sensing device may include a PMOS transistor having a gate connected to the output terminal of the operational amplifier and a source connected to the feedback terminal. The sensing resistor may be connected between the drain of the PMOS transistor and the ground voltage terminal.

In one or more embodiments, when the target current flows in the first direction, the current flowing through the first transistor circuit may flow to the sensing resistor as the first sensing current. The first sensing current has a uniform sensing ratio with respect to the target current.

In one or more embodiments, when the target current flows in the second direction, the current flowing through the third transistor circuit may flow to the sensing resistor as the second sensing current. The second sensing current has a uniform sensing ratio with respect to the target current.

In one or more embodiments, the current sensing system may determine, by the processor (e.g., the processor 11 of FIG. 6), whether the current sensing device is operating and whether the direction of the target current is the first direction or the second direction. For example, it may be determined that the current sensing device is not operating when a current does not flow through the target transistor.

In one or more embodiments, operation S140 may further include determining that a current does not flow through the target transistor by the current sensing device, and providing the ground voltage to the first to fourth transistor circuits by the controller in response to determining that the target current does not flow.

In one or more embodiments, operation S140 may further include determining that the current sensing device is not operating, and providing the ground voltage to the first to fourth transistor circuits by the controller in response to determining that the current sensing device is not operating.

According to an embodiment of the present disclosure, a bidirectional current sensing device, a current sensing system including the same, and a method of operating the current sensing system are provided.

In addition, since the plurality of sensing transistors are turned on or off to determine the path of the sensing current depending on the direction of the current flowing through the transistor that is the target of current sensing, separate switching transistors do not need to be provided on the sensing current path. Accordingly, a bidirectional current sensing device with improved accuracy is provided by maintaining a uniform sensing ratio even when the input voltage and temperature applied to the target transistor change.

The above descriptions are detail embodiments for carrying out the present disclosure. Embodiments in which a design is changed simply or which are easily changed may be included in the present disclosure as well as an embodiment described above. In addition, technologies that are easily changed and implemented by using the above embodiments may be included in the present disclosure. Therefore, the scope of the present disclosure should not be limited to the above-described embodiments and should be defined by not only the claims to be described later, but also those equivalent to the claims of the present disclosure.

What is claimed is:

1. A current sensing device for measuring a target current flowing through a target transistor connected between a first voltage terminal and a second voltage terminal, the current sensing device comprising:
a sensing transistor circuit comprising a first transistor circuit, a second transistor circuit, a third transistor circuit, and a fourth transistor circuit; and
an operational amplifier connected to the sensing transistor circuit,
wherein the first transistor circuit is connected between the first voltage terminal and a first input terminal of the operational amplifier,
wherein the second transistor circuit is connected between the first voltage terminal and a second input terminal of the operational amplifier,
wherein the third transistor circuit is connected between the second voltage terminal and the first input terminal of the operational amplifier,
wherein the fourth transistor circuit is connected between the second voltage terminal and the second input terminal of the operational amplifier,
wherein, based on the target current flowing in a first direction from the first voltage terminal to the second voltage terminal, the first transistor circuit and the fourth transistor circuit are turned on based on a first gate voltage, and the second transistor circuit and the third transistor circuit are turned off based on a second gate voltage, and
wherein, based on the target current flowing in a second direction opposite to the first direction, the first transistor circuit and the fourth transistor circuit are turned off based on the second gate voltage, and the second transistor circuit and the third transistor circuit are turned on based on the first gate voltage.

2. The current sensing device of claim 1, wherein based on the target current flowing in the first direction, the target current is measured based on a first sensing current flowing through the first transistor circuit, and
wherein based on the target current flowing in the second direction, the target current is measured based on a second sensing current flowing through the third transistor circuit.

3. The current sensing device of claim 1, wherein the first input terminal of the operational amplifier is connected to a feedback terminal to receive a feedback voltage, and
wherein the current sensing device further comprises:
a P-channel metal-oxide-semiconductor (PMOS) transistor having a gate for receiving an output voltage of the operational amplifier and a source connected to the feedback terminal; and
a sensing resistor connected between a drain of the PMOS transistor and a ground voltage terminal, and
wherein the current sensing device is configured to measure the target current based on a sensing voltage signal across both ends of the sensing resistor.

4. The current sensing device of claim 3, wherein the current sensing device is further configured to obtain a sensing current based on the sensing resistor and the sensing voltage signal, and
wherein a ratio of the sensing current and the target current is a sensing ratio.

5. The current sensing device of claim 1, wherein the second gate voltage is greater than a ground voltage level, and
wherein the first gate voltage is greater than the second gate voltage.

6. The current sensing device of claim 1, wherein when the current sensing device is not operating, a ground voltage is applied as a gate voltage to each of the first transistor circuit, the second transistor circuit, the third transistor circuit, and the fourth transistor circuit.

7. The current sensing device of claim 1, wherein a first magnitude of the first gate voltage is the same as a second magnitude of a voltage applied to a gate of the target transistor.

8. The current sensing device of claim 1, wherein each of the first transistor circuit, the second transistor circuit, the third transistor circuit, and the fourth transistor circuit comprises at least one sensing transistor, and
wherein the at least one sensing transistor and the target transistor are a same transistor type.

9. The current sensing device of claim 8, wherein each of the at least one sensing transistor is an N-channel metal-oxide-semiconductor (NMOS) transistor, and
wherein the target transistor is a second NMOS transistor.

10. The current sensing device of claim 1, wherein each of the first transistor circuit, the second transistor circuit, the transistor circuit, and the fourth transistor circuit comprises two NMOS transistors connected in series.

11. A current sensing system for measuring a target current flowing through a target transistor connected between a first voltage terminal and a second voltage terminal, comprising:
a current sensing device comprising a sensing transistor circuit and an operational amplifier connected to the sensing transistor circuit, the sensing transistor circuit comprising a first transistor circuit, a second transistor circuit, a third transistor circuit and a fourth transistor circuit; and
a controller configured to control the current sensing device, and
wherein the first transistor circuit is connected between the first voltage terminal and a first input terminal of the operational amplifier,
wherein the second transistor circuit is connected between the first voltage terminal and a second input terminal of the operational amplifier,
wherein the third transistor circuit is connected between the second voltage terminal and the first input terminal of the operational amplifier,
wherein the fourth transistor circuit is connected between the second voltage terminal and the second input terminal of the operational amplifier, and
wherein the controller is further configured to:
based on the target current flowing in a first direction from the first voltage terminal to the second voltage terminal, based on a first mode signal, apply a first gate voltage to the first transistor circuit and the fourth transistor circuit to turn on the first transistor circuit and the fourth transistor circuit, and apply a second gate voltage to the second transistor circuit and the third transistor circuit to turn off the second transistor circuit and the third transistor circuit, and
based on the target current flowing in a second direction opposite to the first direction, based on a second mode signal, apply the second gate voltage to the first transistor circuit and the fourth transistor circuit to turn off the first transistor circuit and the fourth transistor circuit, and apply the first gate voltage to the second transistor circuit and the third transistor circuit to turn on the second transistor circuit and the third transistor circuit.

12. The current sensing system of claim 11, wherein the controller is further configured to, based on the current sensing device not operating, apply a ground voltage to each of the first transistor circuit, the second transistor circuit, the transistor circuit, and the fourth transistor circuit based on a third mode signal to turn off the first transistor circuit, the second transistor circuit, the transistor circuit, and the fourth transistor circuit.

13. The current sensing system of claim 12, further comprising:
a processor configured to provide the first mode signal, the second mode signal, and the third mode signal to the controller, and
wherein the processor is further configured to:
based on the target current flowing in the first direction, provide the first mode signal to the controller,
based on the target current flowing in the second direction, provide the second mode signal to the controller, and
based on the current sensing device not operating, provide the third mode signal to the controller.

14. The current sensing system of claim 11, wherein the controller comprises:
a third voltage terminal connected to a first gate terminal of the first transistor circuit and a fourth gate terminal of the fourth transistor circuit; and
a fourth voltage terminal connected to a second gate terminal of the second transistor circuit and a third gate terminal of the third transistor circuit, and
wherein, based on the first mode signal, the controller is further configured to form a current mirror between a first power voltage terminal to which the first gate voltage is applied and the third voltage terminal to raise the third voltage terminal to the first gate voltage, and to form a path between a second power voltage terminal to which the second gate voltage is applied and a ground voltage terminal passing through the fourth voltage terminal to raise the fourth voltage terminal to the second gate voltage.

15. The current sensing system of claim 11, wherein the controller comprises:
a third voltage terminal connected to a first gate terminal of the first transistor circuit and a fourth gate terminal of the fourth transistor circuit; and
a fourth voltage terminal connected to a second gate terminal of the second transistor circuit and a third gate terminal of the third transistor circuit, and
wherein the controller is further configured to, based on the second mode signal, form a current mirror between a first power voltage terminal to which the first gate voltage is applied and the fourth voltage terminal to raise the fourth voltage terminal to the first gate voltage, and to form a path between a second power voltage terminal to which the second gate voltage is applied and a ground voltage terminal passing through the third voltage terminal to raise the third voltage terminal to the second gate voltage.

16. A method of operating a current sensing system for measuring a target current flowing through a target transistor connected between a first voltage terminal and a second voltage terminal, wherein the current sensing system includes a current sensing device, a controller controlling the current sensing device, and a processor providing a first mode signal or a second mode signal to the controller, the method comprising:
determining, by the processor, whether the target current flows in a first direction from the first voltage terminal to the second voltage terminal;
providing, by the processor, the first mode signal to the controller based on determining that the target current flows in the first direction; and
providing, by the controller, a first gate voltage to a first transistor circuit and a fourth transistor circuit of the current sensing device and a second gate voltage to a second transistor circuit and a third transistor circuit of the current sensing device, based on the first mode signal,
wherein the first transistor circuit is connected between the first voltage terminal and a first input terminal of an operational amplifier of the current sensing device,
wherein the second transistor circuit is connected between the first voltage terminal and a second input terminal of the operational amplifier,
wherein the third transistor circuit is connected between the second voltage terminal and the first input terminal of the operational amplifier, and
wherein the fourth transistor circuit is connected between the second voltage terminal and the second input terminal of the operational amplifier.

17. The method of claim 16, further comprising:
measuring, by the current sensing device, the target current based on a first sensing current flowing through the first transistor circuit.

18. The method of claim 17, wherein the current sensing device further comprises a sensing resistor through which the first sensing current flows, and
wherein the measuring of the target current based on the first sensing current flowing through the first transistor circuit comprises:
obtaining a sensing voltage signal at both ends of the sensing resistor;
obtaining a first magnitude of the first sensing current based on the sensing resistor and the sensing voltage signal; and
obtaining a second magnitude of the target current based on the first magnitude of the first sensing current and a sensing ratio of the current sensing device.

19. The method of claim 16, further comprising:
determining, by the processor, whether the target current flows in a second direction opposite to the first direction;
providing, by the processor, the second mode signal to the controller in response to determining that the target current flows in the second direction; and
providing, by the controller, based on the second mode signal, the second gate voltage to the first transistor circuit and the fourth transistor circuit of the current sensing device, and providing the first gate voltage to the second transistor circuit and the third transistor circuit of the current sensing device.

20. The method of claim 19, further comprising:
measuring the target current based on a second sensing current flowing through the third transistor circuit by the current sensing device.
